(19) United States
(12) Patent Application Publication
(10) Pub. No.: US 2026/0181820 A1
(43) Pub. Date: Jun. 25, 2026

(54) BRACKET AND SERVER

(71) Applicant: Fulian Precision Electronics ( Tianijn) Co., LTD, Tianjin (CN)

(72) Inventors: JUN-LIN LAI, New Taipei (TW); Tung-Ho Shih, New Taipei (TW)

(21) Appl. No.: 19/207,603

(22) Filed: May 14, 2025

(30) Foreign Application Priority Data
Dec. 20, 2024 (CN) 202411894613.4

(51) Int. Cl. H05K 7/20; H05K 7/14

(52) U.S. Cl. CPC H05K 7/20172; H05K 7/1492; H05K 7/20718

(57) ABSTRACT

A cabinet of a server includes a bracket. The bracket has an upper chassis and a lower chassis. The upper chassis supports fan installation. It includes a bottom board. A holder is on the bottom board's underside. A connector is on the holder's front. The connector links to the fan electrically. The lower chassis has a top board and a front board. The front board has a plug. It includes a front opening. The front opening exposes the plug. The top board has a top opening. The top opening's length exceeds the holder's length. The holder passes through the top opening. The bottom board contacts the top board. The connector aligns behind the front opening. The upper chassis moves forward. The connector passes through the front opening. It inserts into the plug. The fan connects to the plug electrically. This elevates the fan. It optimizes space beneath the fan.

### FIELD

The disclosure herein generally relates to information computing systems, and more particularly relates to a bracket and a server.

### BACKGROUND

Servers are usually equipped with a fan, and the fan sometimes needs to be removed from the server for maintenance or replacement. Usually, the fan is installed or removed vertically, but this results in wasted space at the bottom of the fan, leading to lower space utilization efficiency in the server.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a bracket in a server in an embodiment of the present application.

FIG. 2 is an exploded view of the bracket shown in FIG. 1.

FIG. 3 is a bottom isometric view of an upper chassis of the bracket in FIG. 2.

FIG. 4 is an isometric sectional view of the upper chassis in FIG. 3.

FIG. 5 is an isometric view of a connector of the bracket in FIG. 2.

FIG. 6 is a top isometric view of a lower chassis of the bracket in FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

Currently, servers are internally equipped with a fan, the connector of the fan docks with the plug in the server, and the fan needs to be periodically removed for replacement or maintenance. Due to the compact internal structure of the server, in certain specific cases, the fan must be elevated within the server, meaning there is a space between the bottom of the fan and the server. In such specific cases, the fan is typically installed or removed vertically to achieve docking between the connector of the fan and the plug in the server. However, this results in wasted space at the bottom of the fan, leading to lower space utilization efficiency in the server.

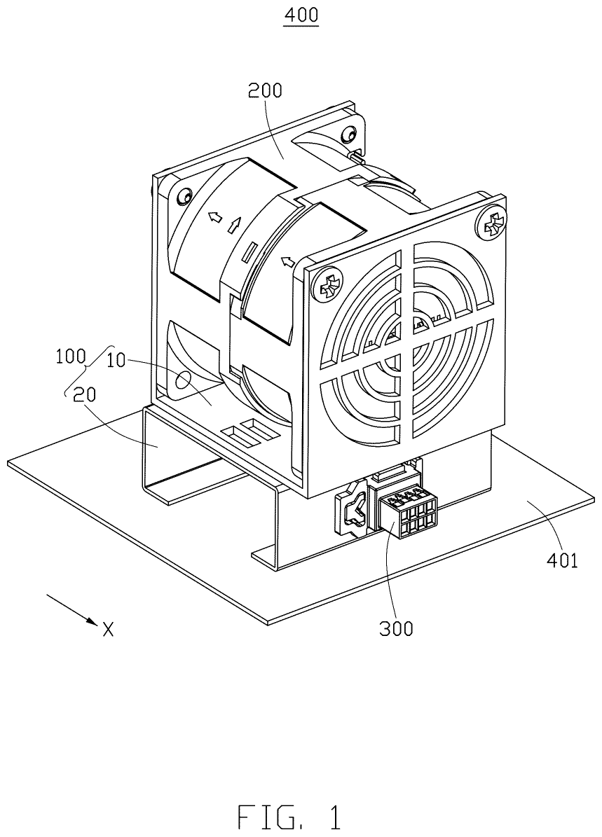

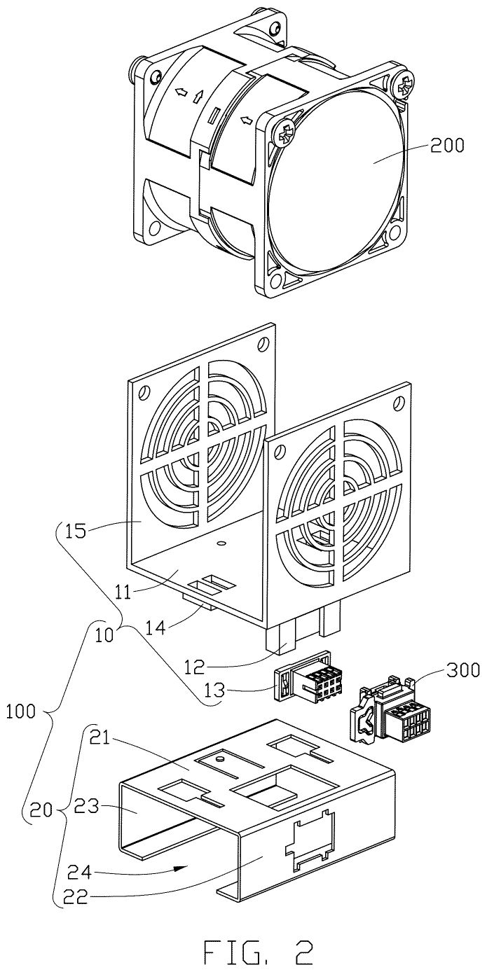

As shown in FIG. 1 and FIG. 2. An embodiment of the present application provides a server 400. The server 400 includes a cabinet 401 and a fan 200. The cabinet 401 includes a bracket 100. The bracket 100 includes an upper chassis 10 and a lower chassis 20. The upper chassis 10 is configured to mount the fan 200. The lower chassis 20 is mounted to the body of the cabinet 401. The upper chassis 10 is detachably connected to the lower chassis 20. Exemplarily, the server 400 can be a personal server or a server system.

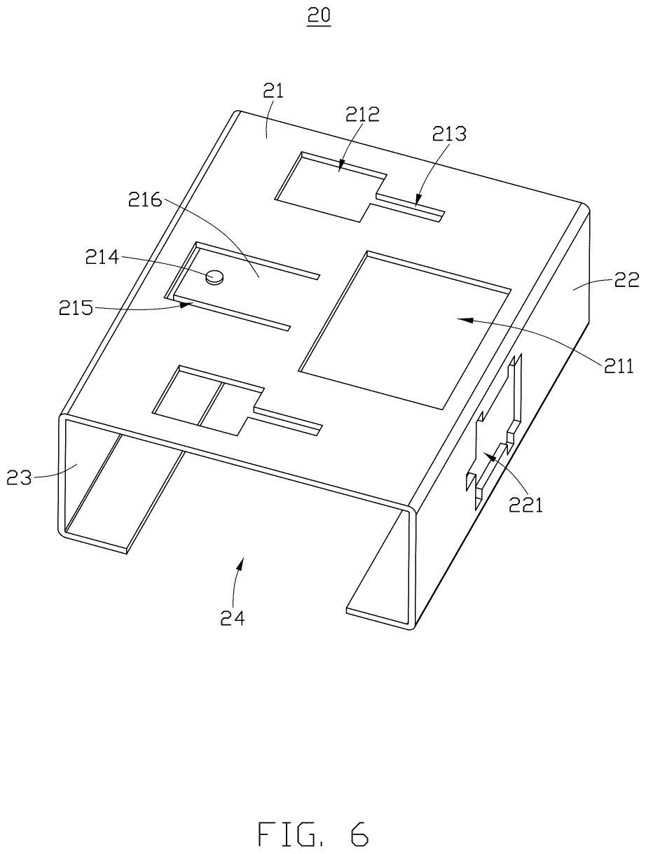

The upper chassis 10 has a cavity 10a. The cavity 10a is configured to accommodate the fan 200. The upper chassis 10 includes a bottom board 11, a holder 12, and a connector 13. The holder 12 is disposed on the bottom surface of the bottom board 11. The connector 13 is disposed on the front side of the holder 12. When the fan 200 is mounted to the upper chassis 10, the connector 13 is electrically connected to the fan 200. For example, the electrical connection is achieved through wires built into the upper chassis 10. The lower chassis 20 includes a top board 21 and a front board 22. The front board 22 is vertically disposed at the front edge of the top board 21 and located below the top board 21. The bottom of the front board 22 is mounted to the body of the cabinet 401. The front board 22 can elevate the top board 21. The top board 21 elevates the upper chassis 10 and the fan 200. The front side of the front board 22 is equipped with a plug 300. The plug 300 is electrically connected to the motherboard of the server 400. As shown in FIG. 6, the front board 22 is provided with a front opening 221. The front opening 221 exposes the plug 300 rearward. The top board 21 is provided with a top opening 211. The total front-to-rear length of the top opening 211 is greater than the total front-to-rear length of the holder 12. This enables the holder 12 to extend into the top opening 211 and move in the front-to-rear direction (insertion direction X shown in FIG. 1) within the top opening 211. The “front” in the present application refers to the direction of the bracket 100 toward the plug 300. The “rear” in the present application refers to the direction of the bracket 100 away from the plug 300.

When installing the upper chassis 10 and the lower chassis 20, the holder 12 is first inserted through the top opening 211 to below the top board 21. This continues until the bottom board 11 of the upper chassis 10 contacts the top board 21 of the lower chassis 20. At this point, the connector 13 is located behind the front opening 221. Then the upper chassis 10 is moved forward. This causes the holder 12 to move forward within the top opening 211. The movement continues until the connector 13 passes through the front opening 221 and is inserted into the plug 300. This electrically connects the fan 200 to the plug 300.

When disassembling the upper chassis 10 and the lower chassis 20, the upper chassis 10 is first moved rearward. This disconnects the connector 13 from the plug 300. Then the upper chassis 10 is removed. This allows the holder 12 to be withdrawn from the top opening 211. This enables the fan 200 to be removed from the cabinet 401 for replacement or maintenance.

In summary, the top board 21 enables the elevation of the fan 200. The holder 12 and the connector 13 can extend into the bottom of the top board 21. This allows more efficient use of the space between the bottom of the fan 200 and the cabinet 401. This improves space utilization efficiency while the fan 200 is elevated. This frees up more space for the cabinet 401.

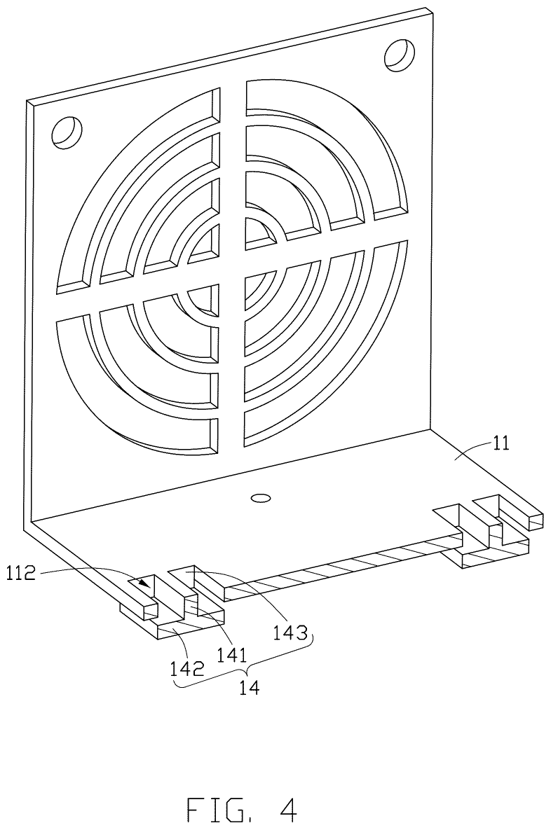

In some embodiments, as shown in FIG. 2 to FIG. 4, the upper chassis 10 further includes a guiding part 14. The guiding part 14 is disposed at the bottom of the bottom board 11. The guiding part 14 includes a vertical board 141 and a horizontal board 142. The horizontal board 142 is positioned parallel to and below the bottom board 11. The vertical board 141 is vertically connected between the horizontal board 142 and the bottom board 11. The vertical board 141 is parallel to the insertion direction X. The top board 21 is provided with a hole 212 and a guiding groove 213. The guiding groove 213 is connected to the front side of the hole 212. The guiding groove 213 extends along the insertion direction X.

When installing the upper chassis 10 and the lower chassis 20, the horizontal board 142 and the vertical board 141 pass through the hole 212. At this point, the horizontal board 142 is located below the top board 21. Then the upper chassis 10 is moved forward. This causes the vertical board 141 to be inserted into the guiding groove 213. The walls of the guiding groove 213 restrict the vertical board 141. This enables the upper chassis 10 to move along the insertion direction X. This allows the connector 13 to be smoothly inserted into the plug 300. Conversely, when disassembling the upper chassis 10 and the lower chassis 20, during the rearward movement of the upper chassis 10, the walls of the guiding groove 213 also restrict the vertical board 141. This enables the connector 13 to be smoothly disconnected from the plug 300.

In some embodiments, as shown in FIG. 2 to FIG. 4, the guiding part 14 further includes a stopping board 143. The stopping board 143 is connected to the rear side of the horizontal board 142 and the vertical board 141. The stopping board 143 is also connected to the bottom board 11. The stopping board 143 is perpendicular to the horizontal board 142 and the vertical board 141. The stopping board 143 is configured to abut against the front wall of the hole 212. When the vertical board 141 moves forward along the guiding groove 213 until the stopping board 143 abuts against the front wall of the hole 212, the upper chassis 10 can no longer move forward relative to the lower chassis 20. At this point, the connector 13 is inserted into the plug 300.

In some embodiments, as shown in FIG. 2 to FIG. 4, the bottom board 11 is provided with an exposure hole 111 on each of the opposite sides of the vertical board 141. The length of each exposure hole 111 is the same as the length of the vertical board 141. The maximum width between the two exposure holes 111 is greater than or equal to the width of the horizontal board 142. When the vertical board 141 moves forward or rearward along the guiding groove 213, the exposure holes 111 are configured to expose the vertical board 141 and the guiding groove 213. This facilitates observation of the movement of the upper chassis 10 relative to the lower chassis 20.

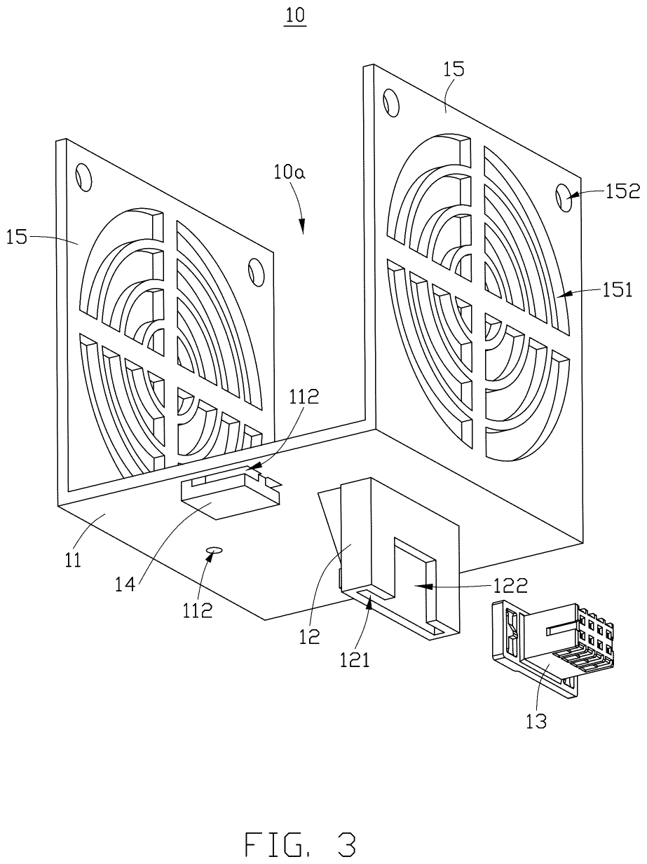

In some embodiments, as shown in FIG. 2, FIG. 3, and FIG. 6, the upper chassis 10 is provided with a positioning hole 112 on the bottom board 11. The lower chassis 20 is provided with a positioning protrusion 214 and a semi-enclosed groove 215 on the top board 21. The semi-enclosed groove 215 forms a deformable region 216 on the top board 21 of the lower chassis 20. The positioning protrusion 214 is disposed in the deformable region 216. The positioning hole 112 is configured to accommodate the positioning protrusion 214. This positions the upper chassis 10 relative to the lower chassis 20.

When installing the upper chassis 10 and the lower chassis 20, the bottom board 11 presses down on the positioning protrusion 214. This causes the deformable region 216 to deform downward below the top board 21. At this point, the positioning hole 112 is not aligned with the positioning protrusion 214. The deformable region 216 remains below the top board 21. When the upper chassis 10 moves into position relative to the lower chassis 20, the positioning protrusion 214 aligns with the positioning hole 112. At this point, the deformable region 216 recovers from deformation. This allows the positioning protrusion 214 to be inserted into the positioning hole 112. When disassembling the upper chassis 10 and the lower chassis 20, the user needs to forcefully lift the rear end of the upper chassis 10. This disconnects the positioning protrusion 214 from the positioning hole 112. Then the upper chassis 10 is moved rearward. At this point, the bottom board 11 presses down on the positioning protrusion 214. This causes the deformable region 216 to remain below the top board 21. This continues until the upper chassis 10 is detached from the lower chassis 20. The deformable region 216 then recovers from deformation.

In other embodiments, when disassembling the upper chassis 10 and the lower chassis 20, the user can also use a tool to deform the deformable region 216 downward below the top board 21. This allows the positioning protrusion 214 to be disconnected from the positioning hole 112. Then the upper chassis 10 is moved rearward.

In some embodiments, as shown in FIG. 2 and FIG. 3, the upper chassis 10 further includes two cover plates 15. The two cover plates 15 are respectively disposed on the front and rear sides of the bottom board 11. The cavity 10a is formed between the bottom board 11 and the two cover plates 15. Each cover plate 15 is provided with a ventilation hole 151 and a mounting hole 152. The mounting hole 152 is configured to mount the fan 200 via screws. The fan 200 blows air toward the cover plate 15. The ventilation hole 151 is configured for ventilation.

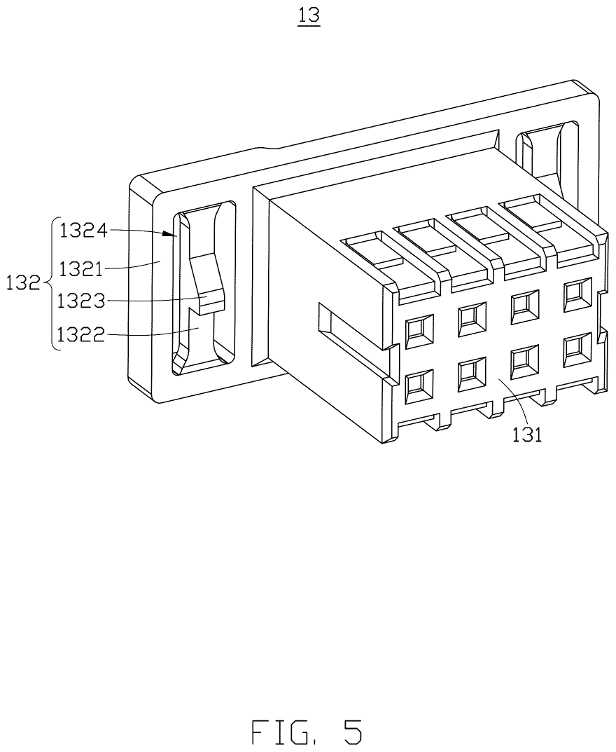

In some embodiments, as shown in FIG. 3 and FIG. 5, the holder 12 is provided with a limiting groove 121. The limiting groove 121 penetrates the bottom of the holder 12 and extends upward within the holder 12. The holder 12 is also provided with an opening 122 on the front side. The opening 122 is connected to the limiting groove 121. The connector 13 includes a body 131 and filling portions 132 on both sides. The filling portions 132 are located within the limiting groove 121. The body 131 extends out of the holder 12 through the opening 122. This enables the connector 13 to be installed into or removed from the holder 12 via the limiting groove 121.

In some embodiments, each filling portion 132 includes a frame 1321, a deformation strip 1322, and a filling protrusion 1323. The frame 1321 encloses a deformation space 1324. The deformation strip 1322 is located within the deformation space 1324 with both ends connected to the frame 1321. The filling protrusion 1323 is disposed on the deformation strip 1322. The filling protrusion 1323 is pressed by the walls of the limiting groove 121 within the limiting groove 121. This increases the friction between the filling portion 132 and the walls of the limiting groove 121. This enhances the stability of the connector 13 within the limiting groove 121.

In some embodiments, as shown in FIG. 2 and FIG. 6, the lower chassis 20 further includes a rear side board 23. The rear side board 23 and the front board 22 are respectively disposed below the front and rear sides of the top board 21. The bottom of the rear side board 23 is mounted to the body of the cabinet 401. The rear side board 23 and the front board 22 jointly elevate the top board 21. An installation space 24 is enclosed between the top board 21, the rear side board 23, and the front board 22. The installation space 24 is configured to accommodate the holder 12, the connector 13, and the deformable region 216.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A cabinet comprising a bracket configured for mounting a fan, the bracket comprising:
an upper chassis comprising a bottom board, a holder mounted on a bottom of the bottom board, and a connector mounted on a front of the holder; and
a lower chassis comprising a top board and a front board, the front board comprising a front opening, the top board comprising a top opening,
wherein a plug is mounted on the front board, when assembling the upper chassis to the lower chassis, the holder is inserted into the top opening until the top board supports the bottom board, then the upper chassis is moved until the connector passes through the front opening and is inserted into the plug, so that the fan is connected to the plug.

2. The cabinet of claim 1, wherein the front board is perpendicular to the top board, the front board is connected to a front edge of the top board and is located underneath the top board, the plug is mounted on a front of the front board and cover the front opening; an insertion direction of the connector being inserted into the plug is defined, a length of the top opening is larger than a length of the holder.

3. The cabinet of claim 2, wherein the upper chassis further comprises a guiding part, the guiding part is mounted on the bottom of the bottom board, the guiding part comprises a vertical board and a horizontal board, the horizontal board is parallel to the bottom board, the vertical board is between the horizontal board and the bottom board, the vertical board is parallel to the insertion direction, the top board comprises a hole and a guiding groove, the guiding groove is connected to a front side of the hole, the guiding groove extends along the insertion direction, when assembling the upper chassis and the lower chassis, the horizontal board and the vertical board is inserted into the hole, after the horizontal board is underneath the top board, the upper chassis is moved forward and the vertical board is inserted into the guiding groove, the guiding groove is configured for guiding the vertical board, so that the upper chassis moves along the insertion direction.

4. The cabinet of claim 3, wherein the guiding part further comprises a stopping board, the stopping board is located at a rear side of the horizontal board and the vertical board, the stopping board is located at the bottom of the bottom board, the stopping board is perpendicular to the horizontal board and the vertical board, when the connector is inserted into the plug, the stopping board contacts an edge of the hole, to stop the upper chassis from moving in the insertion direction.

5. The cabinet of claim 3, wherein the bottom board is provided with an exposure hole on each of the opposite sides of the vertical board, each exposure hole having a length equal to the length of the vertical board, and the maximum width between the two exposure holes being greater than or equal to the width of the horizontal board, when the vertical board moves forward along the guiding groove, the exposure holes expose the vertical board and the guiding groove.

6. The cabinet of claim 2, wherein the upper chassis is provided with a positioning hole on the bottom board, and the lower chassis is provided with a positioning protrusion and a semi-enclosed groove on the top board, the semi-enclosed groove forms a deformable region on the top board, the positioning protrusion is located within the deformable region, the positioning hole is configured to receive the positioning protrusion to align the upper chassis with the lower chassis, during the assembly of the upper chassis and the lower chassis, the bottom board presses the positioning protrusion, causing the deformable region to deform toward the top board until the positioning protrusion aligns with the positioning hole, allowing the positioning protrusion to insert into the positioning hole.

7. The cabinet of claim 2, wherein the upper chassis comprises a cavity, the cavity is configured to accommodate the fan, the upper chassis further comprises two cover plates, the two cover plates are respectively disposed on the front and rear sides of the bottom board, the cavity is formed between the bottom board and the two cover plates, each cover plate is provided with ventilation holes and mounting holes, the mounting holes is configured to install the fan, the fan blows air toward the cover plates and expels air from the cavity through the ventilation holes.

8. The cabinet of claim 2, wherein the holder is provided with a limiting groove, the limiting groove penetrates the bottom of the holder and extends upward within the holder, the holder further comprises an opening on the front side, the opening is communicated with the limiting groove, the connector comprises a body and filling portions on both sides of the body, the filling portions are located in the limiting groove, and the body extends out of the holder through the opening.

9. The cabinet of claim 8, wherein the filling portion includes a frame, a deformation strip, and a filling protrusion, the frame encloses a deformation space, the deformation strip is in the deformation space and both ends of the deformation strip are connected to the frame, the filling protrusion is disposed on the deformation strip, the filling protrusion is compressed by an edge of the limiting groove.

10. The cabinet of claim 6, wherein the lower chassis further includes a rear side board, the rear side board is disposed below the rear side of the top board, the front board is disposed below the front side of the top board, an installation space is formed between the top board, the rear side board, and the front board, the installation space is configured to accommodate the holder, the connector, and the deformable region.

11. A server comprising:
a fan;
a plug configured for powering the fan;
a cabinet comprising a bracket configured for mounting the fan, the bracket comprising:
an upper chassis comprising a bottom board, a holder mounted on a bottom of the bottom board, and a connector mounted on a front of the holder; and
a lower chassis comprising a top board and a front board, the front board comprising a front opening, the top board comprising a top opening,
wherein the plug is mounted on the front board, when assembling the upper chassis to the lower chassis, the holder is inserted into the top opening until the top board supports the bottom board, then the upper chassis is moved until the connector passes through the front opening and is inserted into the plug, so that the fan is connected to the plug.

12. The server of claim 11, wherein the front board is perpendicular to the top board, the front board is connected to a front edge of the top board and is located underneath the top board, the plug is mounted on a front of the front board and cover the front opening; an insertion direction of the connector being inserted into the plug is defined, a length of the top opening is larger than a length of the holder.

13. The server of claim 12, wherein the upper chassis further comprises a guiding part, the guiding part is mounted on the bottom of the bottom board, the guiding part comprises a vertical board and a horizontal board, the horizontal board is parallel to the bottom board, the vertical board is between the horizontal board and the bottom board, the vertical board is parallel to the insertion direction, the top board comprises a hole and a guiding groove, the guiding groove is connected to a front side of the hole, the guiding groove extends along the insertion direction, when assembling the upper chassis and the lower chassis, the horizontal board and the vertical board is inserted into the hole, after the horizontal board is underneath the top board, the upper chassis is moved forward and the vertical board is inserted into the guiding groove, the guiding groove is configured for guiding the vertical board, so that the upper chassis moves along the insertion direction.

14. The server of claim 13, wherein the guiding part further comprises a stopping board, the stopping board is located at a rear side of the horizontal board and the vertical board, the stopping board is located at the bottom of the bottom board, the stopping board is perpendicular to the horizontal board and the vertical board, when the connector is inserted into the plug, the stopping board contacts an edge of the hole, to stop the upper chassis from moving in the insertion direction.

15. The server of claim 13, wherein the bottom board is provided with an exposure hole on each of the opposite sides of the vertical board, each exposure hole having a length equal to the length of the vertical board, and the maximum width between the two exposure holes being greater than or equal to the width of the horizontal board, when the vertical board moves forward along the guiding groove, the exposure holes expose the vertical board and the guiding groove.

16. The server of claim 12, wherein the upper chassis is provided with a positioning hole on the bottom board, and the lower chassis is provided with a positioning protrusion and a semi-enclosed groove on the top board, the semi-enclosed groove forms a deformable region on the top board, the positioning protrusion is located within the deformable region, the positioning hole is configured to receive the positioning protrusion to align the upper chassis with the lower chassis, during the assembly of the upper chassis and the lower chassis, the bottom board presses the positioning protrusion, causing the deformable region to deform toward the top board until the positioning protrusion aligns with the positioning hole, allowing the positioning protrusion to insert into the positioning hole.

17. The server of claim 12, wherein the upper chassis comprises a cavity, the cavity is configured to accommodate the fan, the upper chassis further comprises two cover plates, the two cover plates are respectively disposed on the front and rear sides of the bottom board, the cavity is formed between the bottom board and the two cover plates, each cover plate is provided with ventilation holes and mounting holes, the mounting holes is configured to install the fan, the fan blows air toward the cover plates and expels air from the cavity through the ventilation holes.

18. The server of claim 12, wherein the holder is provided with a limiting groove, the limiting groove penetrates the bottom of the holder and extends upward within the holder, the holder further comprises an opening on the front side, the opening is communicated with the limiting groove, the connector comprises a body and filling portions on both sides of the body, the filling portions are located in the limiting groove, and the body extends out of the holder through the opening.

19. The server of claim 18, wherein the filling portion includes a frame, a deformation strip, and a filling protrusion, the frame encloses a deformation space, the deformation strip is in the deformation space and both ends of the deformation strip are connected to the frame, the filling protrusion is disposed on the deformation strip, the filling protrusion is compressed by an edge of the limiting groove.

20. The server of claim 16, wherein the lower chassis further includes a rear side board, the rear side board is disposed below the rear side of the top board, the front board is disposed below the front side of the top board, an installation space is formed between the top board, the rear side board, and the front board, the installation space is configured to accommodate the holder, the connector, and the deformable region.
